(19) United States
(12) Patent Application Publication
(10) Pub. No.: US 2017/0093384 A1
(43) Pub. Date: Mar. 30, 2017

(54) ACTIVE TRUE TIME DELAY APPARATUS AND OPERATING METHOD THEREOF

(71) Applicant: Electronics and Telecommunications Research Institute, Daejeon (KR)

(72) Inventors: Dong Hwan SHIN, Daejeon (KR); Seong Mo MOON, Daejeon (KR); In Bok YOM, Daejeon (KR); Dong Pil CHANG, Daejeon (KR); Jin Cheol JEONG, Daejeon (KR)

(73) Assignee: Electronics and Telecommunications Research Institute, Daejeon (KR)

(21) Appl. No.: 15/214,738

(22) Filed: Jul. 20, 2016

(30) Foreign Application Priority Data
Sep. 24, 2015 (KR) 10-2015-0135245

(51) Int. Cl. H03K 5/134

(52) U.S. Cl. CPC H03K 5/134; H03K 2005/00195

(57) ABSTRACT

Provided is an active true time delay apparatus for delaying a time and producing a gain in a superhigh frequency band using a field effect transistor (FET) and a similar semiconductor device. The active true time delay apparatus may include a delayer configured to delay an input signal for a predetermined length of time using at least one FET element connected in a distributed amplifier structure and an outputter configured to output the delayed input signal, and the delayer is disposed on a transmission line between an inputter and the outputter.

### CROSS-REFERENCE TO RELATED APPLICATION

This application claims the priority benefit of Korean Patent Application No. 10-2015-0135245, filed on Sep. 24, 2015, at the Korean Intellectual Property Office, the disclosure of which is incorporated herein by reference.

### BACKGROUND

1. Field of the Invention

Embodiments relate to a true time delay apparatus used in connection with a super high frequency band, and more particularly, to an active true time delay apparatus and an operating method thereof that delays a time and produces a gain in a super high frequency band using a field effect transistor (FET) or a similar semiconductor device.

2. Description of the Related Art

A true time delay apparatus is a component used for generating a time delay difference, for example, a time phase difference, of each array element, for example, an antenna, in order to steer a beam of an antenna in a broadband active phase array system. In an image radar system using a large antenna and a wide bandwidth, a beam squinting phenomenon may occur while a beam is being steered due to a time delay difference according to a frequency between an array element and a wave front. Such beam squinting phenomenon may be reduced by a method of removing a delay time difference between array elements using the true time delay apparatus.

A generally used manual true time delay apparatus may cause insertion loss, and the insertion loss may increase in proportion to the delay time. Thus, a true time delay apparatus to produce a gain in a broadband and compensate for such insertion loss may be required.

### SUMMARY

According to an aspect, there is provided an active true time delay apparatus including a delayer configured to delay an input signal for a predetermined length of time using at least one field effect transistor (FET) element connected in a distributed amplifier structure, and an outputter configured to output the delayed input signal, wherein the delayer is disposed on a transmission line between an inputter and the outputter.

The active true time delay apparatus may further include an adjuster configured to adjust a delay time of the input signal passing through the transmission line.

The adjuster may include at least one variable capacitance element of a varactor and a switch element.

The at least one FET element may be connected in a plurality of levels and the delayer may be configured to delay the input signal by a length of time in proportion to a number of the levels.

The delayer may be configured to adjust a gain of the input signal by equalizing a value of an inductor connected to an outside of the at least one FET element and a value of a capacitance included in the at least one FET element with a characteristic impedance of the transmission line.

As an example, which is not intended to be limiting, a drain and a gate of the at least one FET element may be connected to an inductor on the transmission line, and a source of the at least one FET element may be grounded.

According to another aspect, there is provided an active true time delay apparatus for delaying an input signal passing through a transmission line between an input end and an output end, the apparatus including a delayer configured to delay an input signal for a predetermined length of time using at least one field effect transistor (FET) element connected in a distributed amplifier structure, and an adjuster configured to adjust a delay time of the input signal, the adjuster connected to the delayer.

The adjuster may include at least one variable capacitance element of a varactor and a switch element.

The at least one FET element may be connected in a plurality of levels and the delayer may be configured to delay the input signal by a length of time in proportion to a number of the levels.

The delayer may be configured to adjust a gain of the input signal by equalizing a value of an inductor connected to an outside of the at least one FET element and a value of a capacitance included in the at least one FET element with a characteristic impedance of the transmission line.

A drain and a gate of the at least one FET element may be connected to an inductor on the transmission line, and a source of the at least one FET element may be grounded.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIGS. 1A through 1C are diagrams illustrating an example of a general type of a manual true time delay apparatus according to an example embodiment;

FIG. 2 is a block diagram illustrating an example of an active true time delay apparatus according to an example embodiment;

FIG. 3 is a diagram illustrating an example of a circuit configuration of an active true time delay apparatus according to an example embodiment;

FIG. 4 is a diagram illustrating an example of a configuration of an active true time delay apparatus according to an example embodiment; and

FIG. 5 is a flowchart illustrating an example of an operating method of an active true time delay apparatus according to an example embodiment.

### DETAILED DESCRIPTION

Hereinafter, reference will now be made in detail to embodiments of the present invention, examples of which are illustrated in the accompanying drawings, wherein like reference numerals refer to the like elements throughout. Embodiments are described below to explain the present invention, referring to the figures.

The terms used herein are mainly selected from general terms currently being used in light of functions in the present disclosure. Yet, other terms may be used depending on the development of and/or changes in technology, a custom, or a preference of an operator.

In addition, in a specific case, the most appropriate terms are arbitrarily selected by the applicant for ease of description and/or for ease of understanding. In this instance, the meanings of the arbitrarily used terms will be clearly explained in the corresponding description. Hence, the terms should be understood not by the terms per se but by the meanings of the terms and the following overall description of this specification.

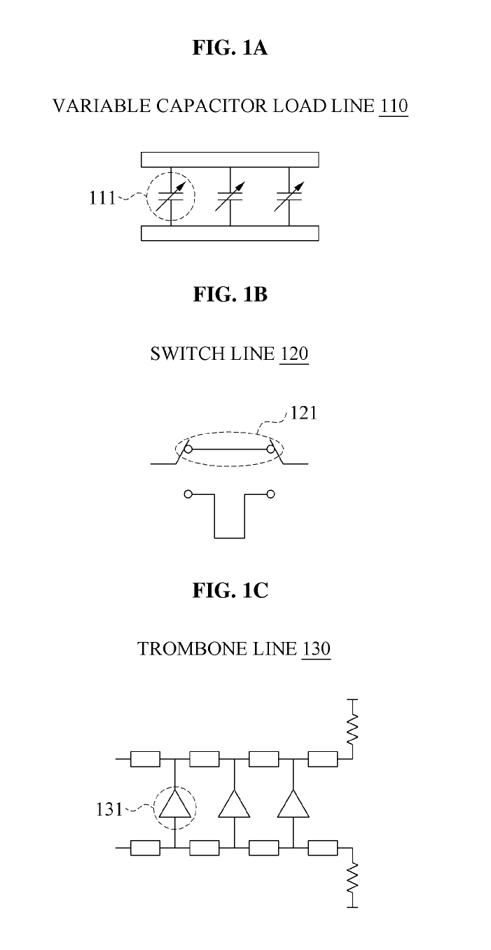

FIGS. 1A through 1C are diagrams illustrating an example of a general type of a manual true time delay apparatus according to an example embodiment.

FIG. 1A illustrates a true time delay apparatus 110 using a variable capacitor load line, FIG. 1B illustrates a true time delay apparatus 120 using a switch line, and FIG. 1C illustrates a true time delay apparatus 130 using a trombone line.

The true time delay apparatus 110 using the variable capacitor load line may delay a time by changing a load value of at least one variable capacitor 111 connected to a transmission line. The true time delay apparatus 120 using the switch line in FIG. 1B may delay a time by selecting one of paths having different lengths of delay time using a switch 121 connectable to a plurality of paths. The true time delay apparatus 130 using the trombone line in FIG. 1C may delay a time by changing a path of a signal using at least one amplifier or at least one switch connected to a transmission line.

Such manual true time delay apparatuses may cause insertion loss according to a time delay, and the insertion loss may increase in proportion to the delay time. In addition, the insertion loss may occur when a manual true time delay apparatus selects a path. To overcome such issue, a method of compensating for insertion loss using an amplifier with a manual true time delay apparatus and a method of consistently maintaining the insertion loss using an attenuator with a variable gain attenuator (VGA) may be used, however, the aforementioned methods may have a limitation in that a size and complexity of a true time delay apparatus are increased.

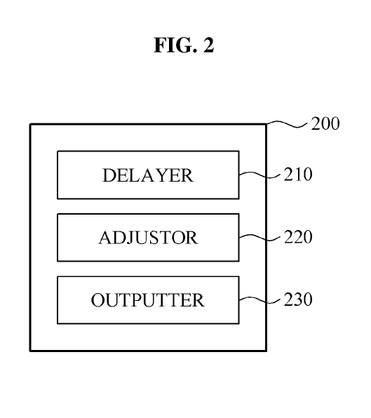

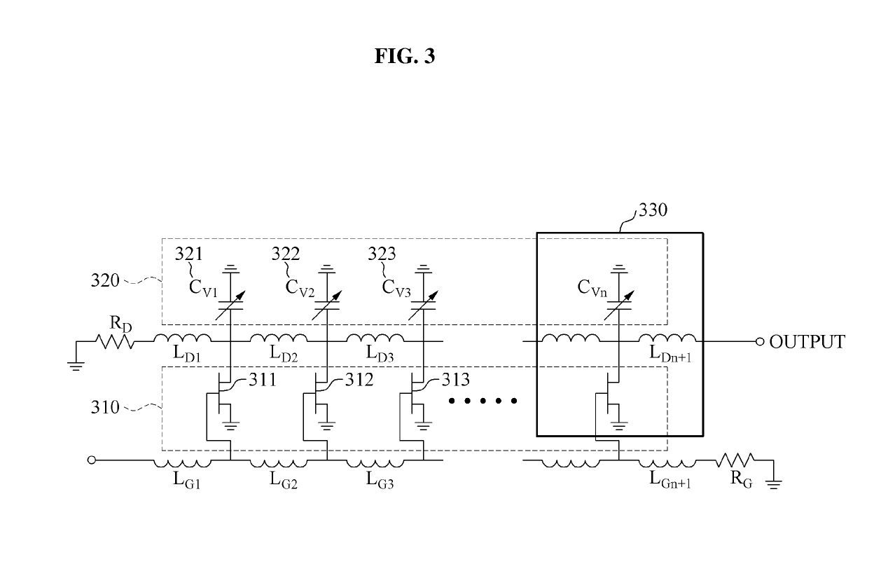

FIG. 2 is a block diagram illustrating an example of an active true time delay apparatus 200 according to an example embodiment.

To overcome an issue of insertion loss occurring in a general manual true time delay apparatus, the active true time delay apparatus 200 may produce a gain in a broadband and stably delay a time by implementing a true time delay apparatus in a distributed amplifier structure using a field effect transistor (FET) or a similar semiconductor device. The active true time delay apparatus 200 includes a delayer 210, an adjuster 220, and an outputter 230. For example, the adjustor 220 or the outputter 230 may be omitted.

The delayer 210 may delay an input signal for a predetermined length of time using at least one FET element connected in a distributed amplifier structure. The delayer 210 is disposed in the distributed amplifier structure on a transmission line between an inputter and an outputter of the active true time delay apparatus 200, and the delayer 210 may delay the input signal passing through the transmission line by the predetermined length of time. The delayer 210 may be provided in a multi-level structure in which the at least one FET element is connected in a plurality of levels, and the delayer 210 may delay the input signal by a length of time in proportion to a number of the connected levels. The delayer 210 may be provided as an amplifier operating in a broadband by adjusting a gain of the input signal by equalizing a value of an inductor connected to an outside of the at least one FET element and a value of a capacitance included in the at least one FET element with a characteristic impedance of the transmission line. A drain and a gate of the at least one FET element are connected to an external inductor disposed on the transmission line, and a source of the at least one FET element is grounded.

The adjustor 220 may be connected to one side of the delayer 210 and may adjust a delay time of the input signal. The adjustor 220 may be provided using a variable capacitance element, for example, a varactor and a switch element, and a true time delay apparatus may be provided in an analog type or a digital type based on an operation method of the variable capacitance element.

The outputter 230 outputs the input signal delayed in the delayer 210.

The active true time delay apparatus 200 may be provided in a basic configuration of the delayer 210 having the distributed amplifier structure in addition to the adjuster 220 including the variable capacitance element for time delay adjustment of the transmission line, thereby producing a gain in the broadband to increase a total gain.

FIG. 3 is a diagram illustrating an example of a circuit configuration of an active true time delay apparatus according to an example embodiment.

The active true time delay apparatus 200 of FIG. 2 may be provided as illustrated in a circuit diagram of FIG. 3. In FIG. 3, an active true time delay apparatus has a basic structure in a form in which at least one field effect transistor (FET) element 310 is connected to a transmission line between an input end and an output end in a distributed amplifier structure. By adding at least one variable capacitance element 320 to the basic structure, a delay time of the transmission line may be adjusted. The at least one FET element 310 and the at least one variable capacitance element 320 may correspond to the delayer 210 and the adjuster 220 of the active true time delay apparatus 200, respectively.

The at least one FET element 310 may allow a capacitor and an inductor included in each of FET elements including a FET element 311, a FET element 312, and a FET element 313 to perform a same role as a transmission line and thus, the at least one FET element 310 may be provided as an amplifier operating in a broadband. Each of the FET elements may be connected in a multi-level structure in which each of the FET elements is connected in a plurality of levels, and each of the FET elements may delay a time of a signal input to the transmission line in proportion to a number of the connected levels. A drain portion and a gate portion of the at least one FET element 310 are connected to inductors L_{D1}, L_{D2}, L_{D3}, . . . L_{DN+1}, L_{G1}, L_{G2}, L_{G3}, . . . L_{GN+1} disposed on the transmission line and a source portion of the at least one FET element 310 is grounded.

The at least one variable capacitance element 320 adjusts the delay time of the signal input to the transmission line. Each of variable capacitance elements including a variable capacitance element 321, a variable capacitance element 322, and a variable capacitance element 323 is connected to each of one of sides of the FET elements to adjust the time delay of the transmission line such that the active true time delay apparatus has a gain in the broadband. The variable capacitance elements may include at least one of a varactor and a switch element. When the FET elements are connected in a multi-level structure, the FET elements may be provided such that a number of the variable capacitance elements corresponds to a number of the FET elements, and each of the variable capacitance elements may be provided by a method of adjusting the delay time of the FET elements for each level.

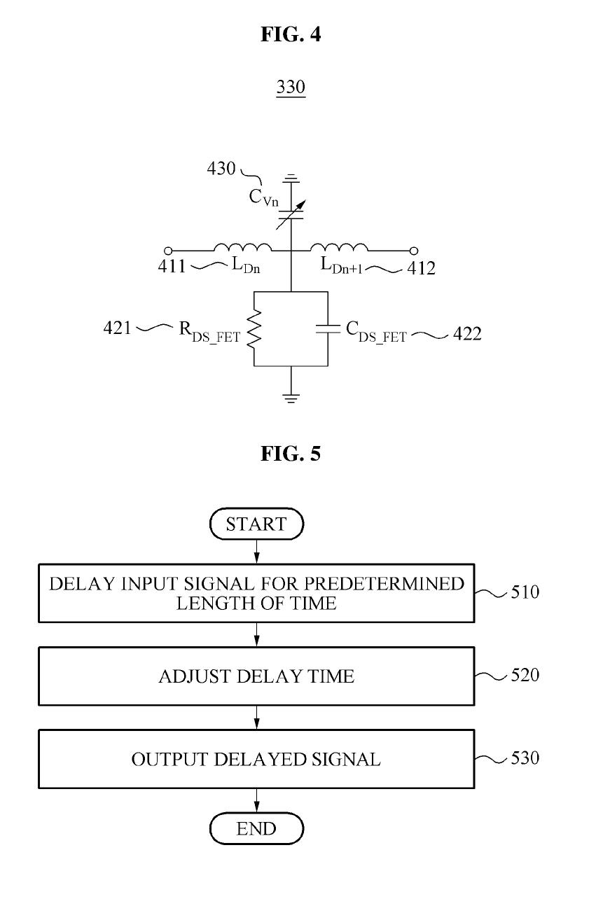

An operating process of a detail circuit 330 of a variable capacitance element and an FET element is illustrated in FIG. 3 and will be described with reference to FIG. 4.

FIG. 4 is a diagram illustrating an example of a configuration of an active true time delay apparatus according to an example embodiment. FIG. 4 illustrates an operating process of the detail circuit 330 of the variable capacitance element and the FET element.

In FIG. 4, a value of a drain resistance R_{DS}_{_}_{FET} 421 of the FET element is a relatively large value and thus, the value of the drain resistance R_{DS}_{_}_{FET} 421 may be ignored. An inductor L_{Dn}, 411 and an inductor L_{Dn+1} 412 connected through a drain of the FET element may adjust a value of a capacitance C_{DS}_{_}_{FET} 422 of the FET element to be identical to a value of a characteristic impedance, for example, 50Ω, of a transmission line. Accordingly, the inductor L_{Dn} 411 and the inductor L_{Dn+1} 412 may obtain a characteristic of amplifying a broadband. A delay time of the transmission line may be adjusted by adding a variable capacitance element 430, for example, a varactor and a switch element, to a basic structure of a distributed amplifier.

An active true time delay apparatus may be provided in a single level or multiple levels. When the active true time delay apparatus is provided in a multi-level structure in which at least one FET element is connected in a plurality of levels, a time, for example, a delay time of an n×1-level true time delay apparatus, may be increased by a length in proportion to a number of an increasing number of levels and a gain of the active true time delay apparatus may be increased according to the delay time. Based on a method of operating a variable capacitance element, for example, a varactor and a switch element, a time may be delayed by an analog method or a digital method in the active true time delay apparatus. When the time is delayed by a digital true time delay apparatus, an individual true time delay apparatus is connected in multiple levels, thereby increasing a total gain.

FIG. 5 is a flowchart illustrating an example of an operating method of an active true time delay apparatus according to an example embodiment.

To overcome an issue of an insertion loss of a general manual true time delay apparatus, the active true time delay apparatus 200 may have a gain in a broadband and stably delay a time by providing a true time delay apparatus in a distributed amplifier structure using a field effect transistor (FET) or a similar semiconductor element.

In operation 510, the delayer 210 of the active true time delay apparatus 200 delays an input signal for a predetermined length of time using at least one FET element connected in a distributed amplifier structure. The delayer 210 is disposed on a transmission line between an inputter and an outputter of the active true time delay apparatus 200 in the distributed amplifier, and delays the input signal passing through the transmission line for the predetermined length of time. The delayer 210 may be provided in a multi-level structure in which the at least one FET element is connected in a plurality of levels, and the delayer 210 may delay the input signal by a length of time in proportion to a number of the connected levels. The delayer 210 may be provided as an amplifier operating in a broadband by adjusting a gain of the input signal by equalizing a value of an inductor connected to an outside of the at least one FET element and a value of a capacitance included in the at least one FET element with a characteristic impedance of the transmission line. A drain and a gate of the at least one FET element are connected to an external inductor disposed on the transmission line, and a source of the at least one FET element is grounded.

In operation 520, the adjuster 220 of the active true time delay apparatus 200 is connected to one side of the delayer 210 and adjusts the delay time of the input signal. The adjuster 220 may be provided using a variable capacitance element, for example, a varactor and a switch element, and a true time delay apparatus may be provided in an analog type or a digital type based on an operation method of the variable capacitance element.

In operation 530, the outputter 230 outputs a signal delayed in the delayer 210.

The active true time delay apparatus 200 may be provided with an added adjuster including a variable capacitance element for time delay adjustment of a transmission line to a basic structure of a delayer in a distributed amplifier structure. Thus, the active true time delay apparatus 200 may have a gain in a broadband thereby increasing a total gain.

The units described herein may be implemented using hardware components and software components. For example, the hardware components may include microphones, amplifiers, band-pass filters, audio to digital convertors, and processing devices. A processing device may be implemented using one or more general-purpose or special purpose computers, such as, for example, a processor, a controller and an arithmetic logic unit, a digital signal processor, a microcomputer, a field programmable array, a programmable logic unit, a microprocessor or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is singular; however, one skilled in the art will appreciate that a processing device may include multiple processing elements and multiple types of processing elements. For example, a processing device may include multiple processors or a processor and a controller. In addition, different processing configurations are possible, such as parallel processors.

A number of examples have been described above. Nevertheless, it should be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. An active true time delay apparatus comprising:
a delayer configured to delay an input signal for a predetermined length of time using at least one field effect transistor (FET) element connected in a distributed amplifier structure; and
an outputter configured to output the delayed input signal,
wherein the delayer is disposed on a transmission line between an inputter and the outputter.

2. The apparatus of claim 1, further comprising:
an adjuster configured to adjust a delay time of the input signal passing through the transmission line.

3. The apparatus of claim 2, wherein the adjuster comprises at least one variable capacitance element of a varactor and a switch element.

4. The apparatus of claim 1, wherein the at least one FET element is connected in a plurality of levels and the delayer is configured to delay the input signal by a length of time in proportion to a number of the levels.

5. The apparatus of claim 4, wherein the delayer is configured to adjust a gain of the input signal by equalizing a value of an inductor connected to an outside of the at least one FET element and a value of a capacitance comprised in the at least one FET element with a characteristic impedance of the transmission line.

6. The apparatus of claim 5, wherein a drain and a gate of the at least one FET element are connected to an inductor on the transmission line, and a source of the at least one FET element is grounded.

7. An active true time delay apparatus for delaying an input signal passing through a transmission line between an input end and an output end, the apparatus comprising:
a delayer configured to delay an input signal for a predetermined length of time using at least one field effect transistor (FET) element connected in a distributed amplifier structure; and
an adjuster configured to adjust a delay time of the input signal, the adjuster connected to the delayer.

8. The apparatus of claim 7, wherein the adjuster comprises at least one variable capacitance element of a varactor and a switch element.

9. The apparatus of claim 7, wherein the at least one FET element is connected in a plurality of levels and the delayer is configured to delay the input signal by a length of time in proportion to a number of the levels.

10. The apparatus of claim 9, wherein the delayer is configured to adjust a gain of the input signal by equalizing a value of an inductor connected to an outside of the at least one FET element and a value of a capacitance comprised in the at least one FET element with a characteristic impedance of the transmission line.

11. The apparatus of claim 10, wherein a drain and a gate of the at least one FET element are connected to an inductor on the transmission line, and a source of the at least one FET element is grounded.

12. An operating method of an active true time delay apparatus, the method comprising:
delaying, by a delayer disposed on a transmission line between an inputter and an outputter, an input signal for a predetermined length of time using at least one field effect transistor (FET) connected in a distributed amplifier structure; and
outputting, by the outputter, the delayed input signal.

13. The method of claim 12, further comprising:
adjusting, by an adjustor connected to one side of the delayer, a delay time of the input signal.

14. The method of claim 13, wherein the adjuster comprises at least one variable capacitance element of a varactor and a switch element.

15. The method of claim 12, wherein the at least one FET element is connected in a plurality of levels, and the delaying of the input signal for the predetermined length of time comprises delaying the input signal by a length of time in proportion to a number of the levels.

16. The method of claim 15, wherein the delaying of the input signal for the predetermined length of time comprises adjusting a gain of the input signal by equalizing a value of an inductor connected to an outside of the at least one FET element and a value of a capacitance comprised in the at least one FET element with a characteristic impedance of the transmission line.
